(19) United States
(12) Patent Application Publication
(10) Pub. No.: US 2013/0313108 A1
(43) Pub. Date: Nov. 28, 2013

(54) MAGNETRON SPUTTERING DEVICE, METHOD FOR CONTROLLING MAGNETRON SPUTTERING DEVICE, AND FILM FORMING METHOD

(71) Applicant: Tokuo Yoshida, Osaka-shi (JP)

(72) Inventor: Tokuo Yoshida, Osaka-shi (JP)

(73) Assignee: SHARP KABUSHIKI KAISHA, Osaka-shi, Osaka (JP)

(21) Appl. No.: 13/984,034

(22) PCT Filed: Feb. 2, 2012
(86) PCT No.: PCT/JP2012/000710

§ 371 Date: Aug. 7, 2013

(30) Foreign Application Priority Data
Feb. 8, 2011 (JP) 2011-024876

(51) Int. Cl. C23C 14/35

(52) U.S. Cl. CPC C23C 14/352
USPC 204/192.15; 204/298.08; 204/192.12

(57) ABSTRACT

A magnetron sputtering device includes alternating current power supplies each connected to a first target and a second target in a pair, and a controller configured to control a phase difference between voltages output from the alternating current power supplies connected to the first targets and the second targets in the pairs adjacent to each other.

### TECHNICAL FIELD

The present invention relates to magnetron sputtering devices, methods for controlling the magnetron sputtering devices, and methods for forming films.

### BACKGROUND ART

As a method for forming a thin film on a surface of a substrate, a sputtering method is generally known. The sputtering method is widely known as a dry process technique indispensable in film forming techniques. The sputtering method is a method in which a rare gas such as Ar gas is introduced into a vacuum container, direct-current (DC) power or high-frequency (RF, AC) power is supplied to a cathode including a target to create glow discharge, thereby forming a film.

The sputtering method includes a magnetron sputtering method in which a magnet is disposed on a back surface of a target in an electrically-grounded chamber, thereby increasing plasma density near a surface of the target so that a film can be formed at a high speed. Such a sputtering method is used in a process of forming a predetermined thin film, for example, on a processed substrate having a large area such as a glass substrate included in a liquid crystal display panel, or the like.

For example, as illustrated in FIG. 8 which is an enlarged cross-sectional view illustrating an example of a substantial portion of a conventional magnetron sputtering device, and in FIG. 9 which is a plan view, Patent Document 1 discloses a magnetron sputtering device 100 including a plurality of first targets 101 and a plurality of second targets 102 which are disposed parallel to a substrate 111 to be processed.

As illustrated in FIG. 9, the plurality of first targets 101 are disposed parallel to each other, and ends of the first targets 101 at one side are connected to each other, so that the first targets 101 altogether form a comb-like shape. In like manner, the plurality of second targets 102 are disposed parallel to each other, and ends of the second targets 102 at one side are connected to each other, so that the second targets 102 altogether form a comb-like shape. The first targets 101 and the second targets are alternately aligned and disposed so that teeth of the comb-like shape of the first targets 101 engage with teeth of the comb-like shape of the second targets 102. One high-frequency power supply 103 is connected to the plurality of first targets 101. Independently of the high-frequency power supply 103, one high-frequency power supply 104 is connected to the plurality of second targets 102.

As illustrated in FIG. 8, a high-frequency current is applied to the first targets 101, and a high-frequency current is applied to the second targets 102, where a phase of the high-frequency current applied to the first targets 101 is shifted by 180° with respect to a phase of the high-frequency current applied to the second targets 102. Glow discharge is created between the first and second targets 101, 102 adjacent to each other in pairs while an anode electrode and a cathode electrode are alternately switched. This creates a plasma atmosphere in the chamber, thereby forming a thin film 111 on a surface of the substrate 110 by sputtering.

Moreover, a sputtering device disclosed in Patent Document 2 includes a plurality of targets disposed in a vacuum chamber, a direct-current power supply and a high-frequency power supply, an impedance matching circuit disposed between the high-frequency power supply and the targets, a switch unit disposed between the direct-current power supply and the targets, and a phaser connected to the high-frequency power supply. A high-frequency current intermittently output from the high-frequency power supply is applied to each target via the impedance matching circuit, and a direct-current intermittently output from the direct-current power supply is superimposed on the high-frequency current. In this way, it is aimed to uniformly and efficiently form a dielectric film on a large substrate.

### CITATION LIST

### Patent Document

PATENT DOCUMENT 1: Japanese Patent Publication No. 2003-96561
PATENT DOCUMENT 2: Japanese Patent Publication No. H11-92925

### SUMMARY OF THE INVENTION

### Technical Problem

However, in the magnetron sputtering device of Patent Document 1, the phase of the high-frequency current applied to all the plurality of first targets is shifted by 180° with respect to the phase of the high-frequency current applied to all the plurality of second targets. Thus, the high-frequency currents applied to the first and second targets in pairs interfere with each other between the pairs adjacent to each other, so that a plasma state becomes unstable.

On the other hand, in the sputtering device of Patent Document 2, in order to stabilize the plasma state, a plurality of high-frequency power supplies are provided, and each high-frequency power supply has to be provided with a phaser, a direct-current power supply, a switch unit configured to control the direct-current power supply, etc., which necessarily increases complexity of the configuration of the device.

The present invention was devised in view of the problems discussed above. It is an objective of the present invention is to stabilize the plasma state without increasing complexity of the configuration of the device.

### Solution to the Problem

To achieve the above objective, a magnetron sputtering device according to the present invention includes: a target section, where a substrate to be processed is arranged to face the target section; alternating current power supplies each configured to supply power to the target section; and a magnet section configured to move back and forth along the target section, wherein a plurality of first targets and a plurality of second targets are alternately disposed in the target section to provide a plurality of pairs each including the first target and the second target adjacent to each other, each of the alternating current power supplies are connected to the first and the second target in the pair, and a controller configured to control a phase difference between voltages output from the alternating current power supplies connected to the first targets and the second targets in the pairs adjacent to each other is provided.

A method for controlling a magnetron sputtering device according to the present invention is a method for controlling a magnetron sputtering device including: a target section, where a substrate to be processed is arranged to face the target section; alternating current power supplies each configured to supply power to the target section; and a magnet section configured to move back and forth along the target section, wherein a plurality of first targets and a plurality of second targets are alternately disposed in the target section to provide a plurality of pairs each including the first target and the second target adjacent to each other, the method including: connecting each of the alternating current power supplies to the first and the second target in the pair, and controlling a phase difference between voltages output from the alternating current power supplies connected to the first targets and the second targets in the pairs adjacent to each other.

A method for forming a film according to the present invention is a method for forming a film on a substrate by a magnetron sputtering device including: a target section, where the substrate to be processed is arranged to face the target section; alternating current power supplies each configured to supply power to the target section; and a magnet section configured to move back and forth along the target section, wherein a plurality of first targets and a plurality of second targets are alternately disposed in the target section to provide a plurality of pairs each including the first target and the second target adjacent to each other, the method including: connecting each of the alternating current power supplies to the first and the second target in the pair, and forming the thin film on a surface of the substrate by controlling a phase difference between voltages output from the alternating current power supplies connected to the first targets and the second targets in the pairs adjacent to each other.

### Advantages of the Invention

According to the present invention, for each of pairs of a first target and a second target, an alternating current power supply is connected to the first target and the second target, and a phase difference between voltages output from the alternating current power supplies connected to the first targets and the second targets in the pairs adjacent to each other is controlled. Thus, it is possible to reduce interference of the voltage applied to the first target in one of the pairs adjacent to each other with the voltage applied to the second target in the other of the pairs, so that a plasma state can be stabilized. Additionally, a direct-current power supply, a switch unit for controlling the direct-current power supply, etc. are no longer necessary, so that it is possible to prevent the complexity of the configuration of the device.

### BRIEF DESCRIPTION OF THE DRAWINGS

FIG. 1 is a cross-sectional view schematically illustrating a configuration of a magnetron sputtering device of a first embodiment.

FIG. 2 is a plan view illustrating a target section of the first embodiment.

FIG. 3 is a plan view illustrating an arrangement relationship between a magnet section and a substrate of the first embodiment.

FIG. 4(a) is a graph illustrating a voltage wave applied to a first target. FIG. 4(b) is a graph illustrating a voltage wave applied to a second target. FIG. 4(c) is a graph illustrating a voltage wave applied to a first target. FIG. 4(d) is a graph illustrating a voltage wave applied to a second target.

FIG. 5(a) is a graph illustrating a voltage wave applied to a first target. FIG. 5(b) is a graph illustrating a voltage wave applied to a second target. FIG. 5(c) is a graph illustrating a voltage wave applied to a first target. FIG. 5(d) is a graph illustrating a voltage wave applied to a second target.

FIG. 6(a) is a graph illustrating a voltage wave applied to a first target. FIG. 6(b) is a graph illustrating a voltage wave applied to a second target. FIG. 6(c) is a graph illustrating a voltage wave applied to a first target. FIG. 6(d) is a graph illustrating a voltage wave applied to a second target.

FIG. 7(a) is a graph illustrating a voltage wave applied to a first target. FIG. 7(b) is a graph illustrating a voltage wave applied to a second target. FIG. 7(c) is a graph illustrating a voltage wave applied to a first target. FIG. 7(d) is a graph illustrating a voltage wave applied to a second target.

FIG. 8 is an enlarged cross-sectional view illustrating an example of a substantial portion of a conventional magnetron sputtering device.

FIG. 9 is an enlarged plan view illustrating an example of a substantial portion of a conventional magnetron sputtering device.

### DESCRIPTION OF EMBODIMENTS

Embodiments of the present invention will be described in detail below with reference to the drawings. The present invention is not limited to the embodiments below.

### First Embodiment of Invention

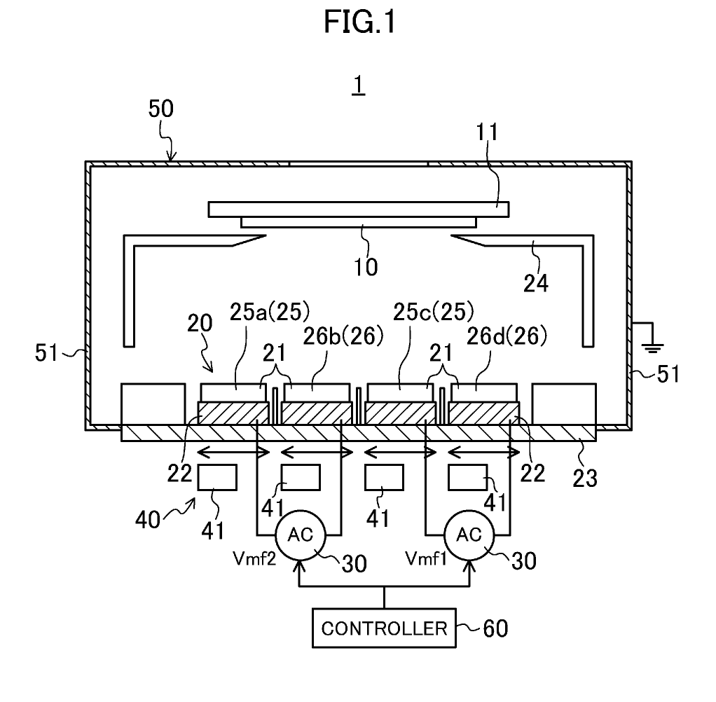

FIGS. 1-4 illustrate a first embodiment of the present invention.

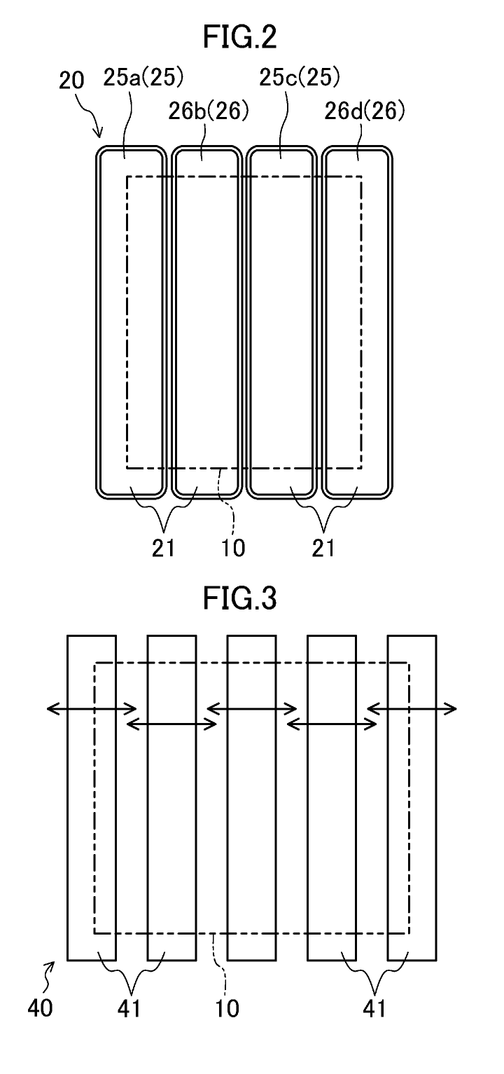

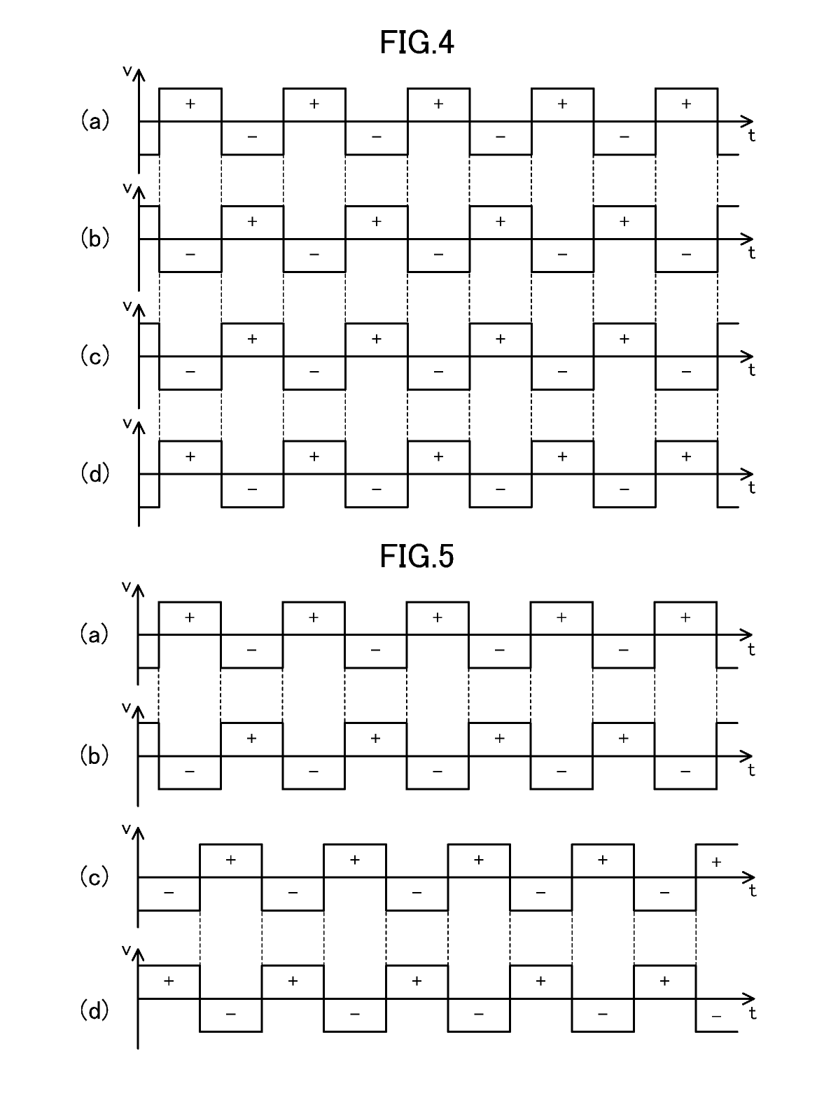

FIG. 1 is a cross-sectional view schematically illustrating a configuration of a magnetron sputtering device 1 of the first embodiment. FIG. 2 is a plan view illustrating a target section 20 of the first embodiment. FIG. 3 is a plan view illustrating an arrangement relationship between a magnet section 40 and a substrate 10 of the first embodiment. FIG. 4 is a graph illustrating voltage waveforms with power supply control of the first embodiment.

As illustrated in FIG. 1, the magnetron sputtering device 1 of the first embodiment includes: a substrate holder 11 configured to hold the substrate 10 on which a process will be performed; the target section 20, where the substrate 10 held by the substrate holder 11 is arranged to face the target section 20; alternating current power supplies 30 each configured to supply power to the target section 20; a magnet section 40 disposed at a back surface side of the target section 20 opposite to the substrate 10; and a chamber 50 configured to accommodate the substrate holder 11 and the target section 20.

The chamber 50 is a vacuum chamber and has an electrically-grounded sidewall 51. A vacuum pump (not shown) is connected to the chamber 50, and the chamber 50 is depressurized by the vacuum pump. Moreover, the chamber 50 includes a gas supply unit (not shown). The gas supply unit is configured to introduce Ar gas and, if needed, O₂ gas into the chamber 50 in a vacuum state.

The substrate 10 is a substrate, such as a glass substrate, included in, for example, a liquid crystal display panel (not shown). The substrate 10 is, for example, 730 mm in length and 920 mm in width. The substrate holder 11 has a lower surface configured to hold the substrate 10, and includes a heater (not shown) configured to heat the substrate 10 in forming a film. Moreover, in the chamber 50, a substrate mask 24 which covers an outer edge portion of a lower surface of the substrate 10 is provided.

As illustrated in FIGS. 1 and 2, first targets 25 and second targets 26 are alternately arranged in the target section 20. The first targets 25 and the second targets 26 are formed, for example, to have the same rectangular plate-like shape, and are arranged in a short side direction of the rectangular plate-like shape (a side-to-side direction in FIGS. 1 and 2, and a later-described moving direction of the magnet section 40) at predetermined intervals. Thus, long-side portions of the first targets 25 are adjacent to long-side portions of the second targets 26.

In the target section 20, a plurality of pairs 21 of the first target 25 and the second target 26 adjacent to each other are provided. The target section 20 of the present embodiment includes two pairs 21 of the first target 25 and the second target 26. That is, as illustrated in FIG. 1, the target section 20 includes a pair 21 of a first target 25a and a second target 26b, and a pair 21 of a first target 25c and a second target 26d.

The first and second targets 25, 26 are made of a material containing, for example, In—Ga—ZnO₄ (IGZO; amorphous oxide semiconductor), ITO, Ti, Al, Mo, Cu, IZO, an Al alloy, or a Cu alloy. The target section 20 is supported by target supporters 22. The target supporters 22 are made of a conductive material such as Cu. The target supporters 22 are disposed on an insulating member 23.

The alternating current power supply 30 is connected to the first and second targets 25, 26 via the target supporters 22 for each of the pairs 21. As illustrated in FIG. 4, the alternating current power supplies 30 are configured to apply alternating-current drive voltages having frequencies which are equal to each other to the target section 20 via the target supporters 22. The drive voltages of the alternating current power supplies 30 each have a frequency lower than or equal to 1 MHz, and the frequency is, for example, about 19-20 kHz.

The magnet section 40 is configured to be moved back and forth along the target section 20 by a drive mechanism (not shown). As illustrated in FIG. 1, the magnet section 40 includes a plurality of magnets 41 arranged at predetermined intervals in the moving direction (in the side-to-side direction in FIG. 1) of the magnet section 40.

As illustrated in FIGS. 1 and 3, the magnets 41 oscillate in synchronization with each other. The speed of oscillation is, for example, about 15-30 mm/s. The width of oscillation of each magnet 41 is substantially equal to the width of each of the first and second targets 25, 26 (that is, the width in the moving direction of the magnet section 40). On the other hand, the width of each magnet 41 is smaller than the width of each of the first and second targets 25, 26. The width of the magnet 41 is, for example, about a half of the width of each of the first and second targets 25, 26.

The magnetron sputtering device 1 includes a controller 60 configured to control a phase difference between the voltages output from the alternating current power supplies 30. In the present embodiment, one controller 60 is connected to the plurality of alternating current power supplies 30 in common. The controller 60 controls the phase difference of the voltages output from the alternating current power supplies 30 connected to the first targets 25 and the second targets 26 in the pairs 21 adjacent to each other.

Here, the graph in FIG. 4(a) illustrates a voltage wave applied to the first target 25a. The graph in FIG. 4(b) illustrates a voltage wave applied to the second target 26b. The graph in FIG. 4(c) illustrates a voltage wave applied to the first target 25c. The graph in FIG. 4(d) illustrates a voltage wave applied to the second target 26d. Moreover, the horizontal axis indicates time (t), and the vertical axis indicates voltage (V).

The controller 60 controls a phase difference θ so that phases of voltages applied to the first target 25c and the second target 26b included in different ones of the pairs 21 and adjacent to each other equal each other (that is, the phase difference θ is 0).

That is, the first target 25c included in the pair 21 on the right of FIG. 1 is adjacent to the second target 26b included in the pair 21 on the left of FIG. 1. Moreover, as illustrated in FIG. 4, frequencies of the voltages applied to the first target 25c and the second target 26b are equal to each other. Moreover, the phases of the voltages applied to the first target 25c and the second target 26b are equal to each other. The input power density of each alternating current power supply 30 is about 1.0-4.0 W/cm².

In this way, glow discharge is created between the first target 25a and the second target 26b in the pair 21 on the left of the figure, and glow discharge is created between the first target 25c and the second target 26d in the pair 21 on the right of the figure. This creates a plasma atmosphere in the chamber 50, thereby forming a thin film on a surface of the substrate 10 by sputtering.

—Control Method and Film Formation Method—

Next, a method for controlling the magnetron sputtering device 1 and a method for forming a film will be described.

To form a film on the substrate 10 by the magnetron sputtering device 1, the substrate 10, which is a glass substrate, is first brought into the chamber 50, and is held by the substrate holder 11. Next, the chamber 50 is depressurized by the vacuum pump (not shown), and the substrate 10 is heated by the heater (not shown) of the substrate holder 11. The targets 25, 26 are made of a material containing, for example, In—Ga—ZnO₄ (IGZO; amorphous oxide semiconductor), ITO, Ti, Al, Mo, Cu, IZO, an Al alloy, or a Cu alloy.

Next, Ar gas, and if necessary, O₂ gas are introduced into the chamber 50 by the gas supply unit (not shown) while a high-vacuum state is maintained. Subsequently, predetermined alternating voltages are applied from the alternating current power supplies 30 to supply power to the target section 20, and the magnet section 40 is allowed to oscillate to start forming the film. The speed of oscillation of the magnet section 40 is, for example, about 15-30 mm/s.

The controller 60 controls the voltages output from the alternating current power supplies 30. That is, for each pair 21 of the first target 25 and the second target 26, the controller 60 controls a phase difference between the voltages applied from the alternating current power supply 30 to the first target 25 and the second target 26 in the pair 21.

Phases of the voltages applied to the first target 25 and the second target 26 included in each pair 21 are shifted by 180° with respect to each other. Thus, as illustrated in the graph of FIG. 4, negative and positive polarities of the voltages are alternated with each other at the same timing in each pair 21.

Moreover, the controller 60 controls the voltages applied to the first target 25c and the second target 26b included in different ones of the pairs 21 and adjacent to each other so that phases of the voltages equal each other, that is, the phase difference θ is 0.

That is, voltages having the same frequency and the same phase are applied to the first target 25c and the second target 26b which are adjacent to each other. Moreover, voltages having the same frequency and the same phase shifted by 180° with respect to the phase of the voltages applied to the first target 25c and the second target 26b are applied to the first target 25a and the second target 26d. The input power density of each alternating current power supply 30 is about 1.0-4.0 W/cm².

In this way, glow discharge is created between the first target 25a and the second target 26b in the pair 21 on the left of the figure, and glow discharge is created between the first target 25c and the second target 26d in the pair 21 on the right of the figure. This creates a plasma atmosphere in the chamber 50, and Ar ionized into positively charged ions by the plasma is attracted to the first targets 25 or the second targets 26. Then, the Ar ions collide with the targets 25, 26, which forces particles to be released from the targets 25, 26. The particles released from the targets 25, 26 attach to the substrate 10, thereby forming a film on the surface of the substrate 10.

### Advantages of First Embodiment

Thus, in the first embodiment, the phase difference θ is controlled by the controller 60 so that the phases of the voltages applied to the first target 25c and the second target 26b included in different ones of the pairs 21 and adjacent to each other equal each other (that is, the phase difference θ is 0). Thus, it is possible to reduce interference of the voltages applied to the first target 25c and the second target 26b with each other. As a result, creating glow discharge between the first target 25 and the second target 26 in each proper pair is ensured, thereby stabilizing a plasma state created in the chamber 50. Moreover, for example, components such as a direct-current power supply, a switch unit for controlling the direct-current power supply, etc. are no longer necessary, so that it is possible to prevent the complexity of the configuration of the device.

### Second Embodiment of Invention

FIG. 5 illustrates a second embodiment of the invention.

FIG. 5 is a graph illustrating voltage waveforms with power supply control of the second embodiment. FIG. 5 (a) is a graph illustrating a voltage wave applied to a first target 25a. FIG. 5 (b) is a graph illustrating a voltage wave applied to a second target 26b. FIG. 5 (c) is a graph illustrating a voltage wave applied to a first target 25c. FIG. 5 (d) is a graph illustrating a voltage wave applied to a second target 26d. The horizontal axis indicates time (t), and the vertical axis indicates voltage (V).

Note that in the following embodiments, the same reference numerals as those shown in FIGS. 1-4 are used to represent equivalent elements, and the detailed explanation thereof will be omitted.

In the first embodiment, the phase difference is controlled so that the phases of the voltages applied to the first target 25c and the second target 26b equal each other. In contrast, in the second embodiment, a difference between the phases can be shifted within a predetermined range.

That is, in the same manner as in the first embodiment, a magnetron sputtering device 1 of the second embodiment includes: a substrate holder 11 configured to hold a substrate 10 on which a process will be performed; a target section 20, where the substrate 10 held by the substrate holder 11 is arranged to face the target section 20; alternating current power supplies 30 each configured to supply power to the target section 20; a magnet section 40 disposed at a back surface side of the target section 20 opposite to the substrate 10; and a chamber 50 configured to accommodate the substrate holder 11 and the target section 20.

Moreover, the target section 20 of the second embodiment includes, in the same manner as in the first embodiment, a pair 21 of the first target 25a and the second target 26b, and a pair 21 of the first target 25c and the second target 26d. The first and second targets 25, 26 are made of a material containing, for example, IGZO, ITO, Ti, Al, Mo, Cu, IZO, an Al alloy, or a Cu alloy.

The magnetron sputtering device 1 includes a controller 60 configured to control a phase difference between voltages output from the alternating current power supplies 30. For each pair 21 of the first target 25 and the second target 26, the controller 60 of the present embodiment controls the phase difference between the voltages applied from the alternating current power supply 30 to the first target 25 and the second target 26 in the pair 21. Phases of the voltages applied to the first target 25 and the second target 26 included in each pair 21 are shifted by 180° with respect to each other.

Moreover, as illustrated in FIG. 5, the controller 60 controls a phase difference θ between voltages applied to the first target 25c and the second target 26b included in different ones of the pairs 21 and adjacent to each other so that the phase difference lies within the range −90°≦θ≦90°.

That is, the controller 60 shifts, as illustrated in FIG. 5, a phase of the voltage applied to the first target 25c by for example, −60° with respect to a phase of the voltage applied to the second target 26b. In other words, the phase difference θ between the first target 25c and the second target 26b is, for example, −60°. With this configuration, it is also possible to satisfactorily stabilize the plasma state.

—Control Method and Film Formation Method—

Next, a method for controlling the magnetron sputtering device 1 and a method for forming a film of the second embodiment will be described.

To form a film on the substrate 10 by the magnetron sputtering device 1, the substrate 10, which is a glass substrate, is first brought into the chamber 50, and is held by the substrate holder 11. Next, the chamber 50 is depressurized by a vacuum pump (not shown), and the substrate 10 is heated by a heater (not shown) of the substrate holder 11.

Next, Ar gas, and if necessary, O₂ gas are introduced into the chamber 50 by a gas supply unit (not shown) while a high-vacuum state is maintained. Subsequently, predetermined alternating voltages are applied from the alternating current power supplies 30 to supply power to the target section 20, and the magnet section 40 is allowed to oscillate at a speed of, for example, about 15-30 mm/s to start forming the film.

The controller 60 controls the voltages output from the alternating current power supplies 30. That is, for each pair of the first target 25 and the second target 26, the controller 60 controls a phase difference between the voltages applied from the alternating current power supply 30 to the first target 25 and the second target 26 in the pair 21. Phases of the voltages applied to the first target 25 and the second target 26 included in each pair 21 are shifted by 180° with respect to each other.

Moreover, the controller 60 controls the voltages applied to the first target 25c and the second target 26b included in different ones of the pairs 21 and adjacent to each other so that frequencies of the voltages equal each other, and the phase difference θ lies within the range −90°≦θ≦90°.

That is, voltages having the same frequency and having phases shifted with respect to each other within the range −90°≦θ≦90° (for example, θ=−60°) are applied to the first target 25c and the second target 26b which are adjacent to each other. The input power density of each alternating current power supply 30 is about 1.0-4.0 W/cm².

In this way, glow discharge is created between the first target 25a and the second target 26b in one of the pairs 21, and glow discharge is created between the first target 25c and the second target 26d in the other of the pairs 21. This creates a plasma atmosphere in the chamber 50, and Ar ionized into positively charged ions by the plasma is attracted to the first targets 25 or the second targets 26. Then, the Ar ions collide with the targets 25, 26, which forces particles to be released from the targets 25, 26. The particles released from the targets 25, 26 attach to the substrate 10, thereby forming a film on the surface of the substrate 10.

### Advantages of Second Embodiment

Thus, in the second embodiment, the phase difference θ between the voltages applied to the first target 25c and the second target 26b included in different ones of the pairs 21 and adjacent to each other is controlled by the controller 60 so that the phase difference θ lies within the range −90°≦θ≦90°. Thus, it is possible to reduce interference of the voltages applied to the first target 25c and the second target 26b with each other. As a result, creating glow discharge between the first target 25 and the second target 26 in each proper pair 21 is ensured, thereby stabilizing a plasma state created in the chamber 50. Moreover, for example, components such as a direct-current power supply, a switch unit for controlling the direct-current power supply, etc. are no longer necessary, so that it is possible to prevent the complexity of the configuration of the device.

That is, when the phase difference θ is smaller than −90°, and when the phase difference θ is larger than 90°, glow discharge is created between the first target 25c and the second target 26b which do not form a proper pair. As a result, the amount of ions contained in plasma generated between the first target 25a and the second target 26b included in one of the pairs 21 is lower than the amount of ions included in plasma generated between the second target 26b included in the one pair 21 and the first target 25c included in the other of the pairs 21. Thus, the voltages applied to the targets 25, 26 in each pair 21 significantly interfere with each other, resulting in an unstable plasma state.

In contrast, when the phase difference θ lies within the range −90°≦θ≦90°, the amount of ions included in the plasma generated between the first target 25a and the second target 26b in the one pair 21 is higher than the amount of ions included in the plasma generated between the second target 26b in the one pair 21 and the first target 25c in the other of the pairs 21. Thus, the voltages applied to the targets 25, 26 in each pair do not significantly interfere with each other, resulting in a stable plasma state. Thus, as described above, when the phase difference θ lies within the range −90°≦θ≦90°, it is possible to satisfactorily stabilize the plasma state.

### Third Embodiment of Invention

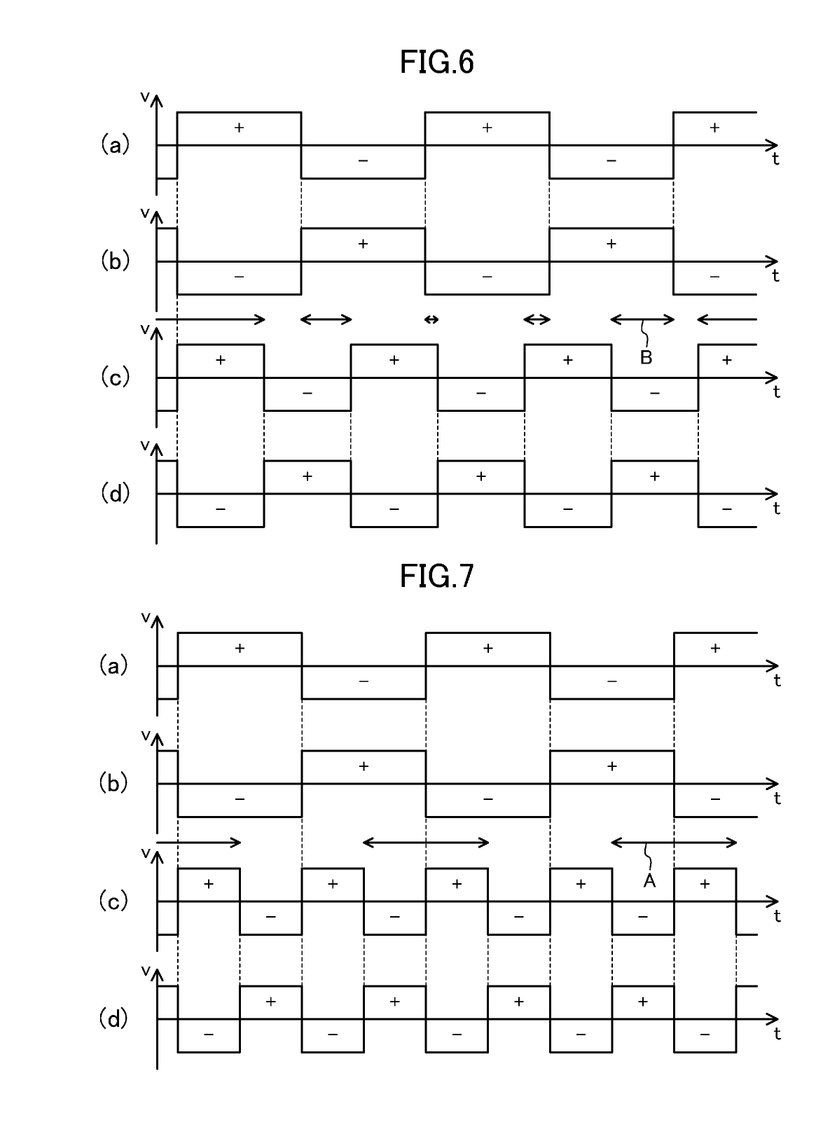

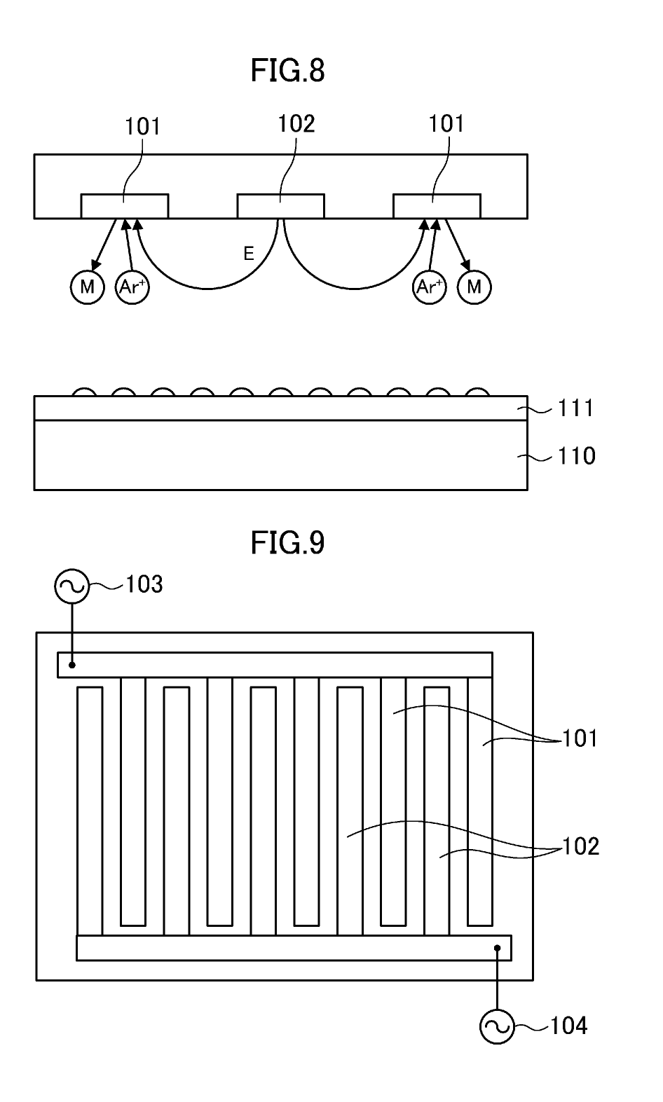

FIG. 6 illustrates a third embodiment of the invention.

FIG. 6 is a graph illustrating voltage waveforms with power supply control of a third embodiment. FIG. 6(a) is a graph illustrating a voltage wave applied to a first target 25a. FIG. 6(b) is a graph illustrating a voltage wave applied to a second target 26b. FIG. 6(c) is a graph illustrating a voltage wave applied to a first target 25c. FIG. 6(d) is a graph illustrating a voltage wave applied to a second target 26d. The horizontal axis indicates time (t), and the vertical axis indicates voltage (V).

In the first and second embodiments, the frequencies of the voltages applied to the targets 25, 26 are equal to each other between the pairs 21. In contrast, in the third embodiment, frequencies of applied voltages differ between pairs 21 depending on predetermined conditions.

That is, in the same manner as in the first and second embodiments, a magnetron sputtering device 1 of the third embodiment includes: a substrate holder 11 configured to hold a substrate 10 on which a process will be performed; a target section 20, where the substrate 10 held by the substrate holder 11 is arranged to face the target section 20; alternating current power supplies 30 each configured to supply power to the target section 20; a magnet section 40 disposed at a back surface side of the target section 20 opposite to the substrate 10; and a chamber 50 configured to accommodate the substrate holder 11 and the target section 20.

Moreover, the target section 20 of the third embodiment includes, in the same manner as in the first and second embodiments, a pair 21 of the first target 25a and the second target 26b, and a pair 21 of the first target 25c and the second target 26d. The first and second targets 25, 26 are made of a material containing, for example, IGZO, ITO, Ti, Al, Mo, Cu, IZO, an Al alloy, or a Cu alloy.

The magnetron sputtering device 1 includes a controller 60 configured to control a phase difference between voltages output from the alternating current power supplies 30. For each pair 21 of the first target 25 and the second target 26, the controller 60 of the present embodiment controls a phase difference between the voltages applied from the alternating current power supply 30 to the first target 25 and the second target 26 in the pair 21. Phases of the voltages applied to the first target 25 and the second target 26 in each pair 21 are shifted by 180° with respect to each other.

The controller 60 controls a phase difference θ between the voltages applied to the first target 25c and the second target 26b included in different ones of the pairs 21 and adjacent to each other so that the phase difference θ lies within the range −90°≦θ≦90°.

Moreover, as illustrated in FIG. 6, one of the alternating current power supplies 30 connected to the first targets 25 and the second targets 26 in the pairs 21 adjacent to each other is configured to output voltages having a frequency which is not the integral multiple of a frequency of voltages output from the other of the alternating current power supplies 30.

That is, as illustrated in FIG. 1 and FIG. 6, voltages applied to the first target 25a and the second target 26b in one of the pairs 21 each have a frequency of, for example, 20 kHz, and voltages applied to the first target 25c and the second target 26d in the other of the pairs 21 each have a frequency of, for example, 30 kHz. That is, the frequency of the voltages output from one of the alternating current power supplies 30 is 1.5 times the frequency of the voltages output from the other of the alternating current power supplies 30.

—Control Method and Film Formation Method—

Next, a method for controlling the magnetron sputtering device 1 and a method for forming a film of the third embodiment will be described.

To form a film on the substrate 10 by the magnetron sputtering device 1, the substrate 10, which is a glass substrate, is first brought into the chamber 50, and is held by the substrate holder 11. Next, the chamber 50 is depressurized by a vacuum pump (not shown), and the substrate 10 is heated by a heater (not shown) of the substrate holder 11.

Next, Ar gas, and if necessary, O₂ gas are introduced into the chamber 50 by a gas supply unit (not shown) while a high-vacuum state is maintained. Subsequently, predetermined alternating voltages are applied from the alternating current power supplies 30 to supply power to the target section 20, and the magnet section 40 is allowed to oscillate at a speed of, for example, about 15-30 mm/s to start forming the film.

The controller 60 controls the voltages output from the alternating current power supplies 30. That is, for each pair of the first target 25 and the second target 26, the controller 60 controls a phase difference between the voltages applied from the alternating current power supply 30 to the first target 25 and the second target 26 in the pair 21. Phases of the voltages applied to the first target 25 and the second target 26 included in each pair 21 are shifted by 180° with respect to each other.

Moreover, the controller 60 controls the voltages applied to the first target 25c and the second target 26b included in different ones of the pairs 21 and adjacent to each other so that the frequencies of the voltages equal each other, and the phase difference θ lies within the range −90°≦θ≦90°. The input power density of each alternating current power supply 30 is about 1.0-4.0 W/cm².

Moreover, one of the alternating current power supplies 30 connected to the first targets 25 and the second targets 26 in the pairs 21 adjacent to each other is configured to output voltages having a frequency which is not the integral multiple of a frequency of voltages output from the other of the alternating current power supplies 30. For example, as illustrated in FIG. 1 and FIG. 6, voltages applied to the first target 25a and the second target 26b of one of the pairs 21 each have a frequency of 20 kHz, and voltages applied to the first target 25c and the second target 26d of the other pair 21 each have a frequency of 30 kHz which is 1.5 times 20 kHz.

In this way, glow discharge is created between the first target 25a and the second target 26b in one of the pairs 21, and glow discharge is created between the first target 25c and the second target 26d in the other of the pairs 21. This creates a plasma atmosphere in the chamber 50, and Ar ionized into positively charged ions by the plasma is attracted to the first targets 25 or the second targets 26. Then, the Ar ions collide with the targets 25, 26, which forces particles to be released from the targets 25, 26. The particles released from the targets 25, 26 attach to the substrate 10, thereby forming a film on the surface of the substrate 10.

### Advantages of Third Embodiment

Here, FIG. 7 is a graph illustrating voltage waveforms with power supply control of a comparative example. FIG. 7(a) is a graph illustrating a voltage wave applied to a first target 25a. FIG. 7(b) is a graph illustrating a voltage wave applied to a second target 26b. FIG. 7(c) is a graph illustrating a voltage wave applied to a first target 25c. FIG. 7(d) is a graph illustrating a voltage wave applied to a second target 26d. The horizontal axis indicates time (t), and the vertical axis indicates voltage (V).

In the comparative example, voltages applied to the first target 25a and the second target 26b of one of the pairs 21 each have a frequency of, for example, 20 kHz, and the voltages applied to the first target 25c and the second target 26d of the other of the pairs 21 each have a frequency of 40 kHz which is 2 times 20 kHz.

In the comparative example, as indicated by the arrow A in FIG. 7, for the first target 25c and the second target 26b included in different ones of the pairs 21 and adjacent to each other, a period A in which the polarities of the applied voltages are different from each other periodically appears for a relatively long time. In the period A, plasma generated between the first target 25a and the second target 26b in a proper pair and between the first target 25c and the second target 26d in a proper pair is reduced. Thus, the amount of sputtering is periodically reduced significantly, and the plasma becomes unstable, which causes a problem where the quality of a thin film formed on the substrate 10 is reduced.

In contrast, according to the third embodiment, as indicated by the arrow B in FIG. 6, a period B in which the polarities of the applied voltages are different from each other can be relatively shortened and split for the first target 25c and the second target 26b. Thus, a period in which plasma between the first target 25a and the second target 26b in the proper pair and between the first target 25c and the second target 26d in the proper pair is reduced is not long and does not periodically appear, so that it is possible to stabilize the state of the plasma, and the quality of the thin film formed by sputtering onto the substrate 10 can be enhanced. Additionally, for example, components such as a direct-current power supply, a switch unit for controlling the direct-current power supply, etc. are no longer necessary, so that it is possible to prevent the complexity of the configuration of the device.

Note that the present invention is not limited to the first to third embodiments. The present invention includes a configuration obtained by accordingly combining the first to third embodiments.

### INDUSTRIAL APPLICABILITY

As described above, the present invention is useful for magnetron sputtering devices, methods for controlling the magnetron sputtering devices, and methods for forming films.

### DESCRIPTION OF REFERENCE CHARACTERS

1 Magnetron Sputtering Device
10 Substrate
11 Substrate Holder
20 Target Section
21 Pair of Targets
25, 25a, 25c First Target
26, 26b, 26d Second Target
30 Power Supply
40 Magnet Section
41 Magnet
60 Controller

1-13. (canceled)

14. A magnetron sputtering device comprising:
a target section, where a substrate to be processed is arranged to face the target section;
alternating current power supplies each configured to supply power to the target section; and
a magnet section configured to move back and forth along the target section, wherein
a plurality of first targets and a plurality of second targets are alternately disposed in the target section to provide a plurality of pairs each including the first target and the second target adjacent to each other,
each of the alternating current power supplies are connected to the first and the second target in the pair,
a controller configured to control a phase difference between voltages output from the alternating current power supplies connected to the first targets and the second targets in the pairs adjacent to each other is provided,
the controller controls a phase difference θ between voltages applied to the first target and the second target included in different ones of the pairs and adjacent to each other so that the phase difference θ lies within the range −90°≦θ≦90°, and
one of the alternating current power supplies connected to the first targets and the second targets in the pairs adjacent to each other is configured to output voltages each having a frequency which is not an integer multiple of a frequency of voltages output from the other of the alternating current power supplies.

15. The magnetron sputtering device of claim 14, wherein
the controller is connected to the alternating current power supplies.

16. A method for controlling a magnetron sputtering device including
a target section, where a substrate to be processed is arranged to face the target section;
alternating current power supplies each configured to supply power to the target section; and
a magnet section configured to move back and forth along the target section, wherein
a plurality of first targets and a plurality of second targets are alternately disposed in the target section to provide a plurality of pairs each including the first target and the second target adjacent to each other, the method comprising:
connecting each of the alternating current power supplies to the first and the second target in the pair, and
controlling a phase difference between voltages output from the alternating current power supplies connected to the first targets and the second targets in the pairs adjacent to each other, wherein
a phase difference θ between voltages applied to the first target and the second target included in different ones of the pairs and adjacent to each other is controlled so that the phase difference θ lies within the range −90°≦θ≦90°, and
one of the alternating current power supplies connected to the first targets and the second targets in the pairs adjacent to each other outputs voltages having a frequency which is not an integer multiple of a frequency of voltages output from the other of the alternating current power supplies.

17. A method for forming a film on a substrate by a magnetron sputtering device including
a target section, where the substrate to be processed is arranged to face the target section;
alternating current power supplies each configured to supply power to the target section; and
a magnet section configured to move back and forth along the target section, wherein
a plurality of first targets and a plurality of second targets are alternately disposed in the target section to provide a plurality of pairs each including the first target and the second target adjacent to each other, the method comprising:
connecting each of the alternating current power supplies to the first and the second target in the pair, and
forming the thin film on a surface of the substrate by controlling a phase difference between voltages output from the alternating current power supplies connected to the first targets and the second targets in the pairs adjacent to each other, wherein
a phase difference θ between voltages applied to the first target and the second target included in different ones of the pairs and adjacent to each other is controlled so that the phase difference θ lies within the range −90°≦θ≦90°, and
one of the alternating current power supplies connected to the first targets and the second targets in the pairs adjacent to each other outputs voltages having a frequency which is not an integer multiple of a frequency of voltages output from the other of the alternating current power supplies.

18. The method of claim 17, wherein
the first target and the second target are made of a material containing In—Ga—ZnO₄.
